(19) United States
(12) Patent Application Publication
(10) Pub. No.: US 2008/0111251 A1
(43) Pub. Date: May 15, 2008

(54) METHOD OF MANUFACTURING AN ELECTRONIC COMPONENT COMPRISING AN INTEGRATED CIRCUIT AND A WINDING ASSEMBLY

(75) Inventors: Frank Bajahr, Bergisch Gladbach (DE); Ruprecht Wiskott, Wiehl-Bielstein (DE); Markus Spreng, Numbrecht (DE)

Correspondence Address: GRIFFIN & SZIPL, PC, SUITE PH-1, 2300 NINTH STREET, SOUTH, ARLINGTON, VA, 22204, US

(73) Assignee: SOKYMAT AUTOMOTIVE GMBH, Reichshof (DE)

(21) Appl. No.: 11/556,339

(22) Filed: Nov. 3, 2006

(30) Foreign Application Priority Data
Nov. 11, 2005 (EP) 05110652.4

(51) Int. Cl. H01L 23/49; H01L 21/58

(52) U.S. Cl. 257/783; 438/118; 257/E23.024; 257/E21.505

(57) ABSTRACT

A method of manufacturing an electronic component comprising an integrated circuit and a core, includes the steps of providing the integrated circuit having at least two accessible contacts, providing the core, assembling the integrated circuit and the core together by means of an adhesive substance, winding a wire on the core in order to produce a winding, bonding or soldering a first end of the wire to a first one of said contacts and bonding or soldering a second end of the wire to a second one of said contacts.

This application claims priority from European Patent Application No. 05110652.4 filed Nov. 11, 2005, the entire disclosure of which is incorporated herein by reference.

### FIELD OF THE INVENTION

The present invention is directed to a method of manufacturing an electronic component comprising an integrated circuit and a winding assembly. The invention is further directed to an electronic component comprising an integrated circuit and a winding assembly.

The term integrated circuit is to be understood in this invention as an integrated circuit in form of an electronic chip, a printed circuit or another discrete electronic element. These electronic elements have very small dimensions and it is usually difficult to assemble such an integrated circuit and a core with a winding around a core and finally bonding the ends of the winding wire to the integrated circuit.

### BACKGROUND OF THE INVENTION

In a conventional method as known from EP-A-0 405 671 the electronic circuit is first fixed to a specially shaped portion of the winding assembly defining the core for the winding. A wire is wound around the core in order to define the winding and the ends of the wire are bonded to the electronic circuit. A drawback of this known method is that the additional step of fixing the core to the electronic circuit has to be carried out.

Another method for manufacturing an electronic component from an integrated circuit and a winding assembly is known from EP 0 573 469 B1. In this known method the integrated circuit and the core are placed on a holding tool and are fixed thereon. The wire is then wound around the core and the ends of the wire are bonded to the contacts of the integrated circuit. When the electronic component is taken out of the holding tool there is no mechanical connection between the integrated circuit and the winding assembly besides the tool wire so that the mechanical forces between the integrated circuit and the winding assembly have to be supported by the wire. Therefore, it is a drawback of this method that the wire ends are stretched during the handling of the electronic component in the manufacturing process due to the mechanical forces acting on the wire.

### SUMMARY OF THE INVENTION

It is an object of the present invention to define a method of manufacturing an electronic component comprising an integrated circuit and a winding assembly which overcomes the drawbacks of the prior art and which reduces the risk of producing minor quality electronic components.

It is another object to the present invention to define an electronic component comprising an integrated circuit and a winding assembly having a higher reliability.

The first object is achieved by the method of manufacturing an electronic component as defined in claim 1.

The method comprises the steps of providing the integrated circuit having at least two accessible contacts, providing the core, assembling the integrated circuit and the core together by means of an adhesive substance, winding a wire on the core in order to produce a winding, bonding or soldering a first end of the wire to a first one of said contacts and bonding or soldering a second end of the wire to a second one of said contacts.

The step of assembling the integrated circuit and the core together by means of an adhesive substance before the wire is wound around the core and before the ends of the wire are bonded or soldered to the contacts of the integrated circuit ensures that the mechanical forces holding the integrated circuit and the core together are supported by the adhesive substance and not by the very thin wires.

In a preferred improvement of the method of the present invention the integrated circuit is placed on a holding tool, then, a predetermined volume of the adhesive substance is applied to at least one end face of the core and the core is then placed on the holding tool in such a manner that the adhesive substance on the core gets into contact with an end face of the integrated circuit. These steps allow assembling the integrated circuit and the core together without contaminating the holding tool with the adhesive substance because the adhesive substance, e.g. a glue is applied to the end face of the core before the core is placed on the holding tool, i.e. outside of the holding tool.

Preferably the end face of the core to which the adhesive substance has been applied is kept in a distance from the opposite end face of the integrated circuit so that a gap is provided between both opposing end faces, wherein adhesive substance is provided in the gap.

It is furthermore preferred that the winding and bonding or soldering steps are carried out while the electronic circuit and the core assembled together are carried in the holding tool. When the electronic circuit and the core assembled together by means of said adhesive substance are held and fixed in the holding tool during the process of winding the wire around the core and bonding or soldering the ends of the wire to the contacts of the electronic circuit the mechanical forces acting on the electronic component during theses steps are supported by the holding tool so that the adhesive substance can cure and the curing process is not disturbed by external mechanical influences.

Preferably the method uses an adhesive substance having such a pot life that the adhesive joint between the integrated circuit and the core is sufficiently hardened after the bonding or soldering step has been finished so that no mechanical holding forces between the integrated circuit and the winding assembly act on the wires when the electronic component is released from the holding tool.

The invention is further defined by an electronic component comprising an integrating circuit having at least two accessible contacts and a core, wherein a wire is wound on the core in order to define a winding assembling, wherein a first end of the wire is bonded or soldered to a first one of said contacts and wherein a second end of the wire is bonded or soldered to a second one of said contacts, and wherein the integrated circuit and the core are mounted together by means of an adhesive substance. This electronic component has a strong mechanical connection between the integrated circuit and the core so that no holding forces between the winding assembly and the integrated circuit act on the wires.

It is preferred that the adhesive substance is a glue.

In a preferred embodiment the integrated circuit and the core are spaced apart and the hardened adhesive substance is provided in the gap between the integrated circuit and the core. Such an electronic component has the advantage that during the assembling of this electronic component the adhesive substance is not squeezed out of the gap between the integrated circuit and the core so that the holding tool is not polluted by the adhesive substance.

### BRIEF DESCRIPTION OF THE DRAWING

A best mode of carrying out the invention is now described with reference to the drawings in which

FIG. 1 is a side view of an electronic component assembled according to the method of the present invention.

### DETAILED DESCRIPTION OF THE INVENTION

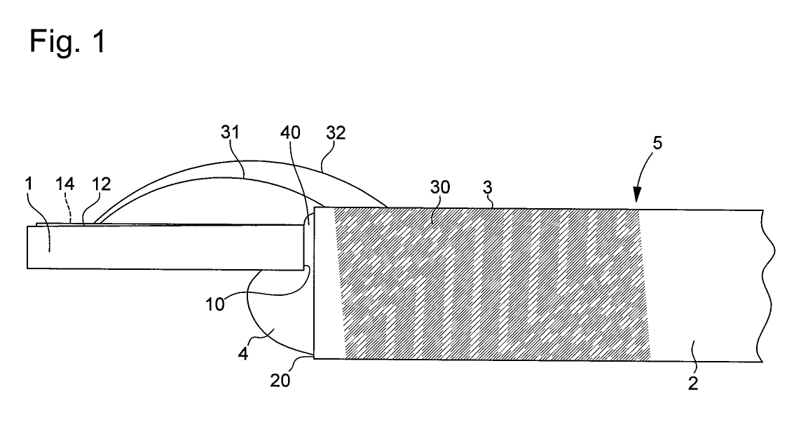

FIG. 1 shows an electronic component 5 that has been manufactured according to the method of the present invention. An integrated circuit 1 and a core 2 for a winding 3 are assembled together by means of an adhesive substance 4.

The adhesive substance 4 has been applied to an end face 20 of core 2 and an end face 10 of the integrated circuit 1 facing the end face 20 of the core 2 has been brought into contact with the adhesive substance 4. A gap 40 is provided between the opposing end faces 10 and 20 wherein the gap 40 is at least partly filled with the adhesive substance 4. Thus, the integrated circuit 1 and the core 2 are not in direct contact with each other.

The winding 3 on the core 2 comprises an electrically conducting wire 30 wound on the core 2. The winding 3 wound on core 2 defines a winding assembly. The first end 31 of the wire 30 and the second end 32 of the wire 30 are connected to electric contacts 12, 14 provided on the upper side of the integrated circuit 1.

The adhesive substance 4 is a fast hardening glue which quickly establishes a considerable strong connection between the core 2 and the electronic component 1 after the electronic circuit 1 and the core 2 have been assembled together and while they are accommodated in the holding tool.

The invention is not restricted to the above-described exemplary embodiment, which only serves for a general explanation of the core concept of the invention. Rather more, it is within the scope of protection that the method of manufacturing an electronic component in accordance with the invention could also adopt different forms than those of the embodiments described above. In particular thereby, the device may comprise features which represent a combination of the respective individual features of the claims.

The reference symbols in the claims, the description and the drawings serve only to provide a better understanding of the invention and are not intended to limit the scope of protection.

What is claimed is:

1. A method of manufacturing an electronic component comprising an integrated circuit and a core, with the steps of:
providing the integrated circuit having at least two accessible contacts, and
providing the core,
wherein the method includes the following successive steps of:
assembling the integrated circuit and the core together by means of an adhesive substance,
winding a wire on the core in order to produce a winding,
bonding or soldering a first end of the wire to a first one of said contacts, and
bonding or soldering a second end of the wire to a second one of said contacts.

2. The method according to claim 1, wherein assembling the integrated circuit and the core together comprises the steps of placing the integrated circuit on a holding tool, applying a predetermined volume of said adhesive substance to at least one end face of the core and placing the core on the holding tool in such a manner that the adhesive substance on the core gets into contact with an end face of the integrated circuit.

3. The method according to claim 2, wherein the winding and bonding or soldering steps are carried out while the electronic circuit and the core assembled together are carried in the holding tool.

4. The method according to claim 1, wherein an adhesive substance is used having such a pot life that the adhesive joint between the integrated circuit and the core is sufficiently hardened after the bonding or soldering step has been finished so that no mechanical holding forces between the integrated circuit and the core act on the wires.

5. The method according to claim 1 wherein the end face of the core to which the adhesive substance has been applied is kept in a distance from the opposite end face of the integrated circuit so that a gap is provided between both opposing end faces, wherein adhesive substance is provided in the gap.

6. An electronic component realised by the manufacturing method according to claim 1, said electronic component comprising an integrated circuit having at least two accessible contacts and a core, wherein a wire is wound on the core in order to define a winding, wherein a first end of the wire is bonded or soldered to a first one of said contacts and wherein a second end of the wire is bonded or soldered to a second one of said contacts, and wherein the integrated circuit and the core are mounted together by means of an adhesive substance.

7. An electronic component according to claim 6, and wherein the adhesive substance is hardened glue.

8. An electronic component according to claim 6, wherein the integrated circuit and the core are spaced apart and in that the hardened adhesive substance is provided in the gap between the integrated circuit and the core.
